(19) United States
(12) Patent Application Publication
(10) Pub. No.: US 2026/0173898 A1
(43) Pub. Date: Jun. 18, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Masanori TANAKA, Matsumoto-city (JP); Takuya OGUCHI, Matsumoto-city (JP)

(73) Assignee: FUJI ELECTRIC CO., LTD., Kawasaki-shi (JP)

(21) Appl. No.: 19/371,838

(22) Filed: Oct. 28, 2025

(30) Foreign Application Priority Data
Dec. 15, 2024 (JP) 2024-212201

(51) Int. Cl. H01L 23/495; H01L 21/48; H01L 21/56; H01L 23/00; H01L 23/31

(52) U.S. Cl. CPC H10W 70/429; H10W 70/048; H10W 74/016; H10W 74/114; H10W 90/756

(57) ABSTRACT

A semiconductor device includes: a semiconductor chip; a lead frame having a die pad at which the semiconductor chip is arranged, and a first lead and a second lead; a wire that connects the lead frame and the semiconductor chip; and a resin that seals the semiconductor chip. The die pad has a first surface and a second surface opposite to each other. The first lead has a first main body portion, a bent portion located at an end of the first main body portion, and an extending portion that extends from the bent portion to the die pad. The second lead has a second main body portion, and an end portion located at an end of the second main body portion inside the resin, and separated from the die pad. A height of the bent portion being higher than a height of the second lead.

### CROSS-REFERENCE TO RELATED APPLICATIONS

The present application claims priority pursuant to 35 U.S.C. § 119 from Japanese patent application number 2024-212201 filed on Dec. 15, 2024, the entire disclosure of which is hereby incorporated by reference herein.

### BACKGROUND

### Technical Field

The present disclosure relates to a semiconductor device and a method of manufacturing the semiconductor device.

### Description of the Related Art

In manufacturing a resin-sealed semiconductor device, a pin for pressing a die pad and an insulating sheet arranged at the bottom surface of the die pad against a mold is used, for example (see Japanese Patent Application Publication Nos.2024-94764 and 2023-142184, for example).

However, the use of the aforementioned pin generally increases the number of steps in manufacturing semiconductor devices.

### SUMMARY

A main aspect of the present disclosure is a semiconductor device, comprising: a semiconductor chip; a lead frame having a die pad at which the semiconductor chip is arranged, and a first lead and a second lead; a wire that connects the lead frame and the semiconductor chip; and a resin that seals the semiconductor chip, the die pad having a first surface at which the semiconductor chip is arranged, and a second surface opposite to the first surface, the first lead having a first main body portion, a bent portion located at an end of the first main body portion, and an extending portion that extends from the bent portion to the die pad, the second lead having a second main body portion, and an end portion that is located at an end of the second main body portion and inside the resin, and is separated from the die pad, with reference to the second surface, a height of the bent portion being higher than a height of the second lead.

Another aspect of the present disclosure is a method of manufacturing a semiconductor device that includes a semiconductor chip, a die pad at which the semiconductor chip is arranged, and a lead frame having a first lead, the first lead having a first main body portion, a bent portion located at an end of the first main body portion, and an extending portion that extends from the bent portion to the die pad, the die pad having a first surface at which the semiconductor chip is arranged, and a second surface opposite to the first surface, the second surface being inclined downward with respect to a horizontal plane with increasing distance from the extending portion, the method comprising: a chip arrangement step of arranging the semiconductor chip at the first surface of the die pad; a connection step of connecting the lead frame and the semiconductor chip with a wire; an arrangement step of arranging, at a first mold, the lead frame and an insulating sheet located on a side of the second surface; a mold clamping step of clamping the first mold and a second mold together; and a filling step of filling a space between the first mold and the second mold with a resin.

### BRIEF DESCRIPTION OF THE DRAWINGS

FIG. 1 is a diagram to describe an internal configuration of a semiconductor device 10.

FIG. 2 is a schematic diagram illustrating a configuration of a part of a semiconductor device 10.

FIG. 3 is a flowchart illustrating a process of manufacturing a semiconductor device 10.

FIG. 4A is a diagram to describe a part of a process of manufacturing a semiconductor device 10.

FIG. 4B is a diagram to describe a part of a process of manufacturing a semiconductor device 10.

FIG. 4C is a diagram to describe a part of a process of manufacturing a semiconductor device 10.

FIG. 4D is a diagram to describe a part of a process of manufacturing a semiconductor device 10.

FIG. 5A is a diagram to describe positions of semiconductor chips 50a1 to 50a3.

FIG. 5B is a diagram to describe a position of a semiconductor chip 50d.

FIG. 6 is a diagram to compare a semiconductor device 10 with a comparative example.

### DETAILED DESCRIPTION

At least following matters will become apparent from the descriptions of the present description and the accompanying drawings. The same or equivalent constituent elements, members, and the like illustrated in the drawings are given the same reference numerals, and repetitive description is omitted as appropriate.

### Semiconductor Device 10 (Internal Configuration)

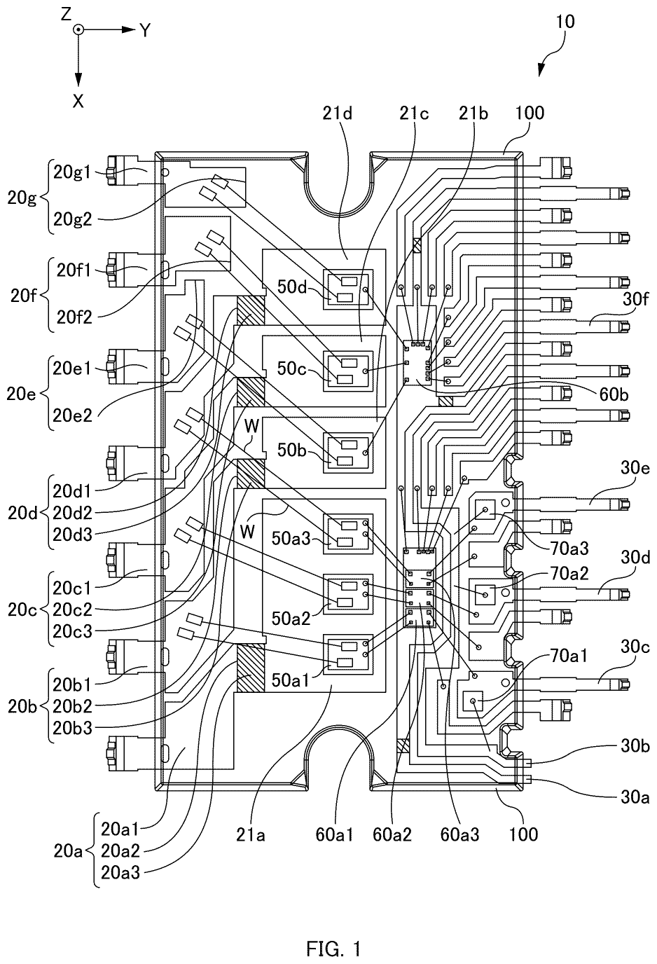

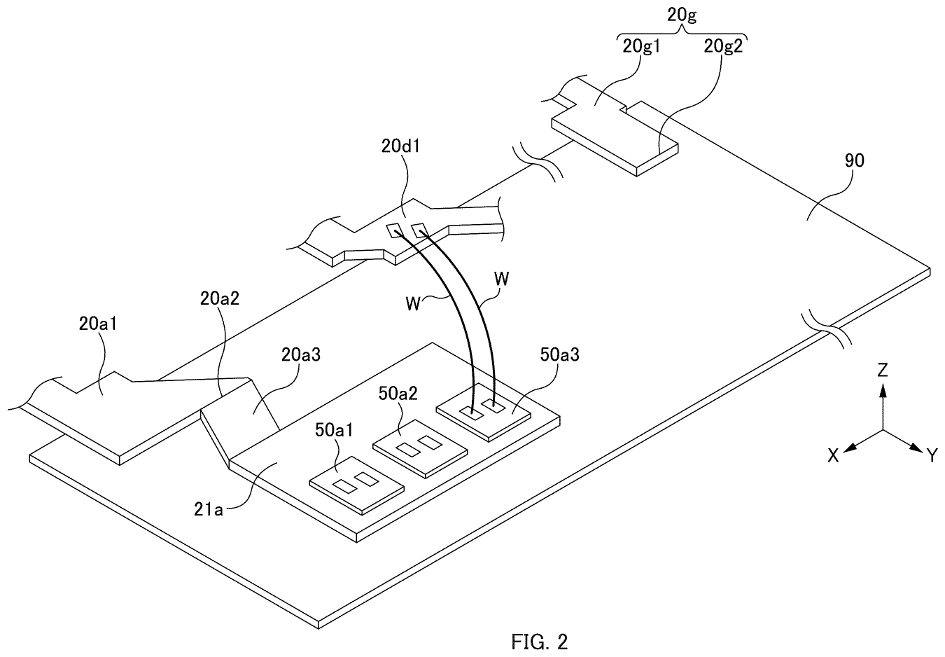

FIG. 1 is a diagram to describe the internal configuration of a semiconductor device 10 according to an embodiment of the present disclosure. FIG. 2 is a schematic diagram illustrating the configuration of a part of the semiconductor device 10.

### Definition of Directions and Others

First, referring to FIG. 1, directions and others in the semiconductor device 10 will be defined. In the longitudinal direction of the semiconductor device 10, the direction from the top toward the bottom in the paper surface is defined as a “+X direction”, and the direction opposite thereto (i.e., the direction from the bottom toward the top in the paper surface in the longitudinal direction) is defined as a “−X direction”.

In the width direction that intersects the longitudinal direction of the semiconductor device 10, the direction from the left toward the right in the paper surface is a “+Y direction”, and the direction opposite thereto (i.e., the direction from the right toward the left in the paper surface in the width direction) is a “−Y direction”. Further, the direction perpendicular to the X direction and the Y direction is defined as a “Z direction”. In an embodiment of the present disclosure, for example, the zenith direction when the semiconductor device 10 is placed at a horizontal surface is defined as a “+Z direction”, and the direction opposite thereto is defined as a “−Z direction”.

Note that both the +X direction and the −X direction may be simply referred to as “X direction”. Similarly, both the +Y direction and the −Y direction may be simply referred to as “Y direction”. Further, both the +Z direction and the −Z direction may be simply referred to as “Z direction”.

In FIG. 1, in order to facilitate understanding of the directions in the semiconductor device 10, each of the +X direction, +Y direction, and +Z direction is given a line segment with an arrow. In the following description, the +X direction may be referred to as “rightward direction”, the −X direction may be referred to as “leftward direction”, and the X direction may be referred to as “left-right direction”. The +Y direction may be referred to as “front direction (or forward)”, the −Y direction may be referred to as “rear direction (or rearward)”, and the Y direction may be referred to as “front-rear direction”. The +Z direction may be referred to as the “upward direction (or front surface direction)”, the −Z direction may be referred to as the “downward direction (or back surface direction)”, and the Z direction may be referred to as “up-down direction” or “height direction”.

The aforementioned definitions of directions and the like are common throughout the present specification unless otherwise specified.

### Details of Semiconductor Device 10

The semiconductor device 10 is an electronic component in which a power semiconductor that drives a load (not illustrated) and a control IC that controls the power semiconductor, and the like are sealed with a resin. The semiconductor device 10 includes, as illustrated in FIGS. 1 and 2, lead frames 20, 30, die pads 21a to 21d, semiconductor chips 50a1 to 50d, 60a1 to 60a3, diodes 70a1 to 70a3, an insulating sheet 90, a resin 100, and multiple wires. In an embodiment of the present disclosure, each of the multiple wires may be referred to as “wire W”, or “wire” without any reference sign for convenience.

In FIG. 1, only the outline of the resin 100 is illustrated in plan view such that the internal configuration of the semiconductor device 10 can be seen, for convenience. In FIG. 2, in order to facilitate understanding of the configuration of the semiconductor device 10, leads 20a, 20d, 20g, the die pad 21a, and the insulating sheet 90 in the semiconductor device 10 are mainly illustrated, for convenience. The details of the semiconductor device 10 will be described below with reference to FIGS. 1 and 2 as appropriate.

The lead frame 20 is a metal member (so-called main current lead frame) to transfer electric current between the power semiconductor and the load, and includes the leads 20a, 20d, 20g and leads 20b, 20c, 20e, 20f.

The lead 20a is a metal plate-shaped member connected to the die pad 21a (described later) where multiple high-side power semiconductors are arranged. As illustrated in the schematic diagram of FIG. 2, the lead 20a has a main body portion 20a1, a bent portion 20a2, and an extending portion 20a3. The main body portion 20a1 is a part extending from the inside of the resin 100 to the outside thereof. The bent portion 20a2 is located at the end of the main body portion 20a1 in the inside of the resin 100, and is a part obtained by bending the extending portion 20a3 of the lead 20a downward (in the −Z direction). The extending portion 20a3 is a part that extends from the bent portion 20a2 and is connected to the die pad 21a

Note that, for example, the lead 20a corresponds to a “first lead” and the main body portion 20a1 corresponds to a “first main body portion”.

The die pad 21a is a metal plate-shaped member having a front surface (surface in the +Z direction) at which the semiconductor chips 50a1 to 50a3 are arranged. The die pad 21a has a substantially quadrilateral shape in plan view. Here, “substantially quadrilateral shape” refers to a shape consisting of four sides including, for example, a square and a rectangle, and may have at least some of corners that is/are cut off at an angle relative to any of the sides. Further, the “substantially quadrilateral shape” may have a cut (recessed part) or a protrusion (projecting part) at a part of any of the sides

The front surface of the die pad 21a corresponds to a “first surface”, and the back surface of the die pad 21a corresponds to a “second surface”. The front surface and the back surface may be parallel to each other.

The semiconductor chip 50a1 is a high-side power semiconductor that is, for example, an Insulated Gate Bipolar Transistor (IGBT), but may be another power semiconductor (for example, a power metal-oxide-semiconductor (MOS)). The semiconductor chips 50a2, 50a3 are the same or similar to the semiconductor chip 50a1, and thus the descriptions thereof are omitted. Further, in FIG. 2, illustration of those other than two wires W connected to the semiconductor chip 50a3 are omitted, for convenience.

As illustrated in FIG. 2, the insulating sheet 90 is attached to the back surface (the surface in the −Z direction) of the die pad 21a. In FIG. 2, only the die pad 21a is illustrated among the die pads 21a to 21d, for convenience, but the respective back surfaces of the die pads 21a to 21d are attached with the insulating sheet 90. The insulating sheet 90 is a resin sheet located at a surface of the semiconductor device 10 in the −Z direction. An embodiment of the present disclosure uses a material with excellent heat dissipation properties, as the insulating sheet 90, and thus the semiconductor device 10 can dissipate the heat of the semiconductor chips 50a to 50d to the outside of the semiconductor device 10.

The leads 20b to 20d in FIG. 1 are metal plate-shaped members that are similar to the lead 20a. Thus, the following describes the leads 20b to 20d, focusing on the differences from the lead 20a.

The lead 20b has a main body portion 20b1, a bent portion 20b2, and an extending portion 20b3. The main body portion 20b1 and the semiconductor chip 50a1 are connected with two wires, and the extending portion 20b3 is connected to the die pad 21b.

The lead 20c has a main body portion 20c1, a bent portion 20c2, and an extending portion 20c3. The main body 20c1 and the semiconductor chip 50a2 are connected with two wires, and the extending portion 20c3 is connected to the die pad 21c.

The lead 20d has a main body portion 20d1, a bent portion 20d2, and an extending portion 20d3. The main body portion 20d1 and the semiconductor chip 50a3 are connected with two wires, and the extending portion 20d3 is connected to the die pad 21d.

In the front side of the die pads 21b to 21d, the semiconductor chips 50b to 50d corresponding to the low-side power semiconductors are arranged, respectively. Each of the die pads 21b to 21d has a substantially quadrilateral shape in plan view. The semiconductor chips 50b to 50d are, for example, Insulated Gate Bipolar Transistors (IGBTs), but may also be other power semiconductors (for example, power MOSs).

The lead 20e is a metal member connected to the semiconductor chip 50b, and has a main body portion 20e1 and an end portion 20e2. The main body portion 20e1 is a part that extends from the inside of the resin 100 to the outside thereof. The end portion 20e2 is a part located at the end of main body portion 20e1 in the inside of the resin 100. In an embodiment of the present disclosure, the main body portion 20e1 and the semiconductor chip 50b are connected with two wires. Further, the end portion 20e2 (i.e., the lead 20e) is separated from all of the die pads located within the semiconductor device 10.

The leads 20f, 20g are metal members that are similar to the lead 20e. Thus, the following describes the leads 20f, 20g, focusing on the differences from the lead 20e.

The lead 20f is a metal member connected to the semiconductor chip 50c, and has a main body portion 20f1 and an end portion 20f2. In an embodiment of the present disclosure, the main body portion 20f1 and the semiconductor chip 50c are connected with two wires. Further, the end portion 20f2 (i.e., the lead 20f) is separated from all of the die pads located within the semiconductor device 10.

The lead 20g is a metal member connected to the semiconductor chip 50d, and has a main body portion 20g1 and an end portion 20g2. In an embodiment of the present disclosure, the main body portion 20g1 and the semiconductor chip 50d are connected with two wires. Further, the end portion 20g2 (i.e., the lead 20g) is separated from all of the die pads located within the semiconductor device 10. Note that the lead 20g corresponds to a “second lead”, and the main body portion 20g1 corresponds to a “second main body portion”.

The lead frame 30 is a lead frame (so-called control lead frame) to exchange various signals between the driver circuit that controls the semiconductor chips 50a1 to 50d, and the outside of the semiconductor device 10, and includes multiple leads 30a to 30f. Note that the lead frame 30 includes multiple leads in addition to the leads 30a to 30f, but the description thereof is omitted here, for convenience.

The lead 30a is a metal plate-shaped member where the semiconductor chips 60a1 to 60a3 that drive the high-side semiconductor chips 50a1 to 50a3 and a semiconductor chip 60b that drives the low-side semiconductor chips 50b to 50d are arranged. Note that a large number of wires are connected to the lead 30a so that the semiconductor chips 60a1 to 60a3 and 60b can appropriately drive the semiconductor chips 50a1 to 50d.

The lead 30b is a metal plate-shaped member to which the wire from the lead 30a and the wires from the diodes 70a1 to 70a3 (described later) are connected.

The lead 30c is a metal plate-shaped member where the diode 70a1 is arranged. The diode 70a1 is a so-called bootstrap diode, and is used in driving the high-side semiconductor chip 50a1.

The leads 30d, 30e are metal plate-shaped members where the diodes 70a2, 70a3 are arranged, respectively, similarly to the lead 30c. Each of the diodes 70a2, 70a3 is a bootstrap diode that is the same or similar to the diode 70a1.

The lead 30f is a metal plate-shaped member to exchange signals and the like with the semiconductor chip 60b. The wire is connected between the lead 30f and the semiconductor chip 60b. The description is given here of only the lead 30f among the multiple leads for exchanging signals and the like with the semiconductor chip 60b, for convenience.

### Method of Manufacturing Semiconductor Device 10

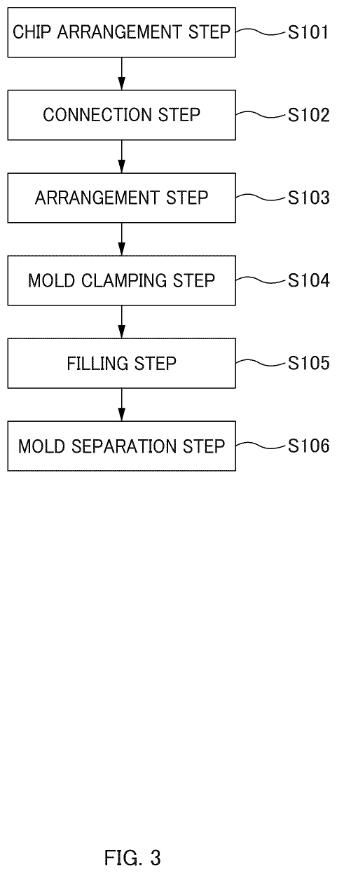

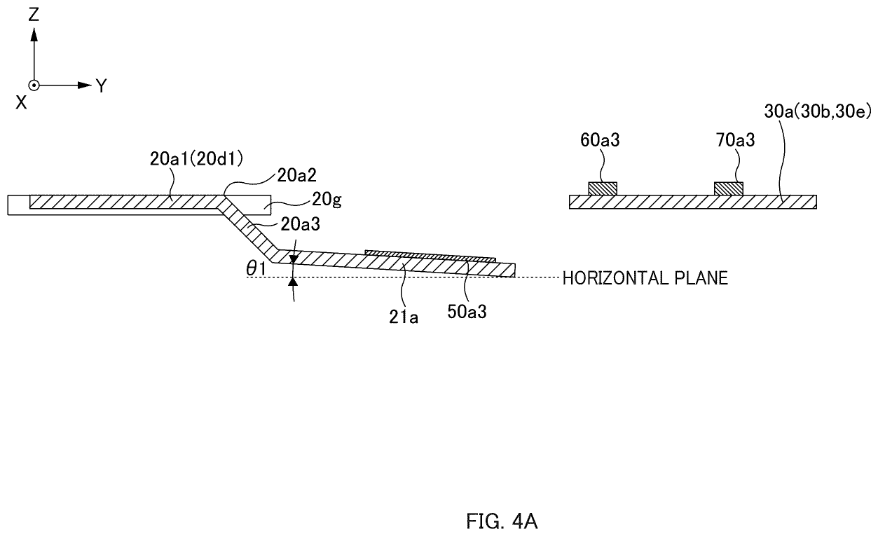

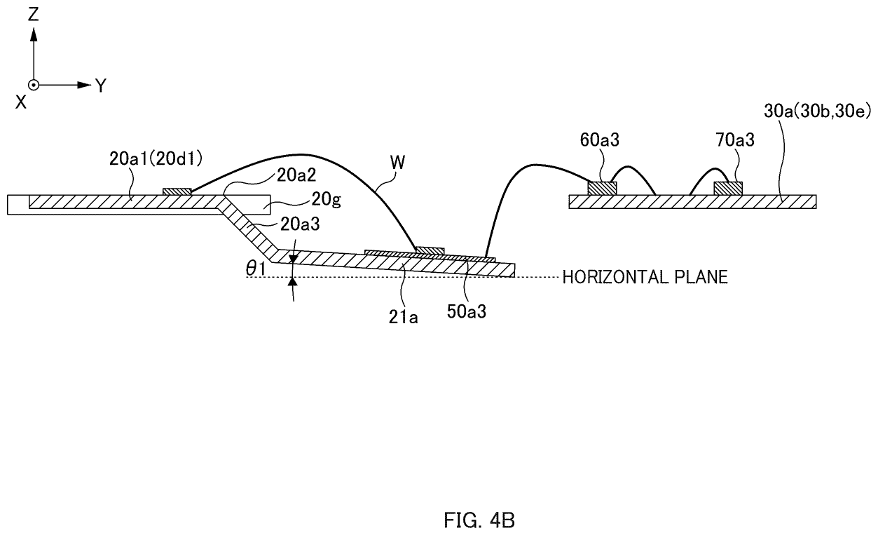

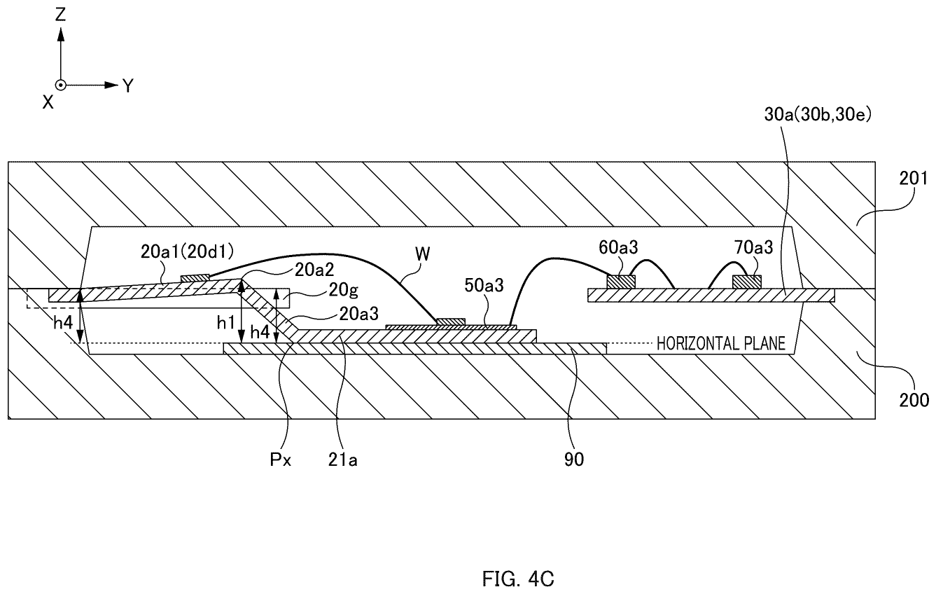

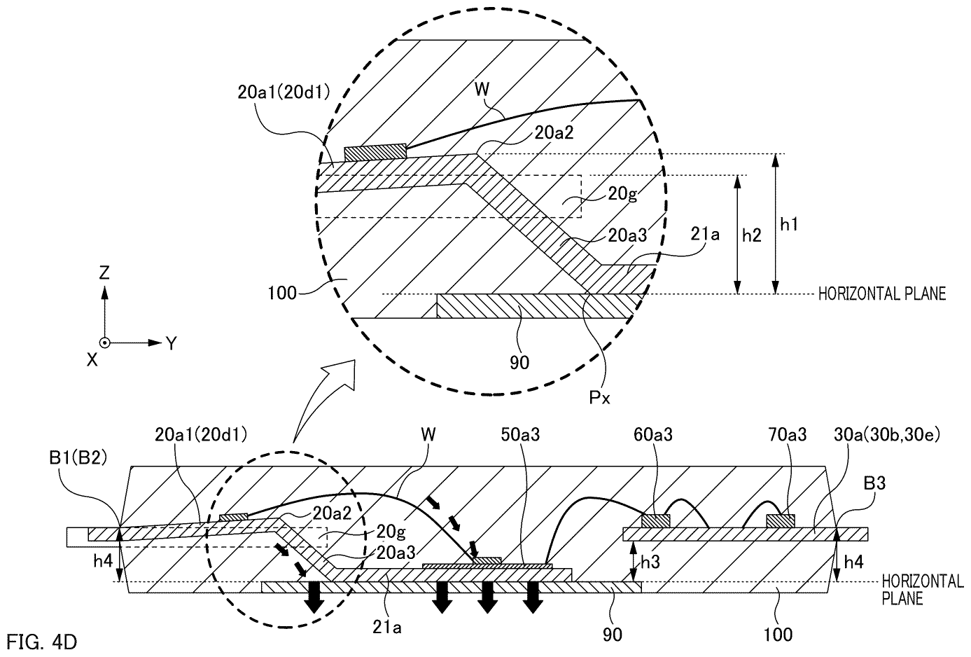

In manufacturing a typical semiconductor device, a pin (not illustrated) is used to press a die pad and an insulating sheet against a mold. The semiconductor device 10 according to an embodiment of the present disclosure can be manufactured in a simple process without using such a pin. The following describes a method of manufacturing the semiconductor device 10 referring to FIGS. 3 and 4A to 4D.

FIG. 3 is an example of a flowchart of the process of manufacturing the semiconductor device 10, and FIGS. 4A to 4D each are a diagram to describe a part of such a manufacturing process. FIGS. 4A to 4D schematically illustrate the positions of some components of the semiconductor device 10 when seen in the direction from the +X direction to the-X direction in a YZ plane. Specifically, FIGS. 4A to 4D schematically illustrate the positions of the leads 20a, 20d, 20g, 30a, 30b, 30e, the die pad 21a, the semiconductor chips 50a3, 60a3, and the diode 70a3 in the YZ plane.

Here, in the FIGS. 4A to 4D, the lead 20d located on the −X side with respect to the lead 20a is at the same height as that of the lead 20a in the Z direction. Furthermore, the thicknesses of the leads 20a and 20d in the Z direction are also the same, and thus illustration thereof is omitted as appropriate.

In an embodiment of the present disclosure, the height of the main body portion 20a1 of the lead 20a at a boundary position B1 (described later) between the inside and the outside of the resin 100 is the same in the Z direction as the height of the main body portion 20g1 of the lead 20g at a boundary position B2 (described later) between the inside and the outside of the resin 100, which will be described below. Furthermore, the thickness of the main body portion 20a1 of the lead 20a in the Z direction is the same as the thickness of the lead 20g in the Z direction. However, FIGS. 4A to 4D illustrate the thickness of the lead 20g in the Z direction as being larger than the thickness of the main body 20a1, in order to facilitate the understanding of the respective positions of the main body portion 20a1 and the lead 20g.

Note that, in an embodiment of the present disclosure, the phrase “the height Ha and the height Hb are the same (height)” refers to that they only needs to be substantially the same height, including manufacturing variations and the like such as those in the lead frame 30 of the semiconductor device 10 and the like, without the need for the heights Ha and Hb to have mathematically the same value. For example, even if the height Ha and the height Hb have a difference of, for example, about 50 μm, they are still substantially the same height. The details of the “boundary position” will be described below.

Further, the leads 30a, 30b, 30e have the same thickness and the same height in the Z direction, and thus only the lead 30a is illustrated here, for convenience, and the leads 30b, 30e located at the rear of the paper plane (positions in the −X direction) are not illustrated.

Note that, in an embodiment of the present disclosure, the boundary position B1 (described later) between the inside and the outside of the resin 100 of the main body portion 20a1 of the lead 20a is at the same height in the Z direction as the height of the main body portion 30a1 of the lead 30a at the boundary position B3 (described later) between the inside and the outside of the resin 100.

First, in the manufacturing process of FIG. 3, the semiconductor chips 50a1 to 50d are arranged at the die pads 21a to 21d, and the semiconductor chips 60a1 to 60b and the diodes 70a1 to 70a3 are arranged at the lead frame 30 (chip arrangement step S1). As a result, as illustrated in FIG. 4A, for example, the semiconductor chip 50a3 is arranged at the die pad 21a, the semiconductor chip 60a3 is arranged at the lead 30a, and the diode 70a3 is arranged at the lead 30e.

The die pad 21a of an embodiment of the present disclosure is inclined, with respect to a horizontal plane (dotted line in FIG. 4A), from the lower end of the extending portion 20a3 of the lead 20a. Specifically, the die pad 21a is inclined downward (that is, in the −Z direction) with respect to the horizontal plane, with increasing distance from the extending portion 20a3 in the +Y direction. Hereinafter, in an embodiment of the present disclosure, the angle formed between the horizontal plane at the lower end of the extending portion 20a3 and the back surface of the plate-shaped die pad 21a is defined as an angle θ1 (>0).

It is assumed here that the die pad 21a is inclined downward with respect to the horizontal plane with increasing distance from the extending portion 20a3, and the die pads 21b to 21d are also similar to the die pad 21a. That is, for example, the die pads 21b to 21d are inclined downward with respect to the horizontal plane with increasing distance from the extending portions 20b3 to d3, respectively. Accordingly, the angle formed between the horizontal plane and the back surface of each of the plate-shaped die pads 21b to 21d is the angle θ1 (>0).

After the chip arrangement step S101 in FIG. 3 is performed, a step of connecting multiple wires in the inside of the semiconductor device 10 in FIG. 1 (so-called wire bonding) is performed (connection step S2). As a result, for example, as illustrated in FIG. 4B, the main body 20d1 of the lead 20d and the semiconductor chip 50a3 are connected with the wire W, and the semiconductor chip 50a3 and the semiconductor chip 60a3 are connected with the wire. Furthermore, the semiconductor chip 60a3 and the lead 30e are connected with the wire, and the diode 70a3 and the lead 30b are connected with the wire.

In FIGS. 4A and 4B, the main body portions 20a1, 20d1, 20g1 and the leads 30a, 30b, 30e are parallel to the horizontal plane. Here, for example, the main body portion 20a1 being parallel to the horizontal plane indicates that the front surface of the main body portion 20a1 is parallel to the horizontal plane. Further, for example, the lead 30a being parallel to the horizontal plane indicates that the front surface of the lead 30a is parallel to the horizontal plane.

After the connection step S102 is performed, the die pads 21a to 21d and the insulating sheet 90 are arranged at the inner bottom surface of a lower mold 200, in a state in which the insulating sheet 90 is attached to the respective back surfaces of the die pads 21a to 21d (see FIG. 2) (arrangement step S103). In an embodiment of the present disclosure, a recess is formed in the inside of the mold 200 such that the inner bottom surface of the mold 200 is parallel to the horizontal plane.

Here, prior to arranging the lead frames 20, 30 in the mold 200, the die pads 21a to 21d and the insulating sheet 90 are fixed together with, for example, an adhesive, but it is not limited thereto. For example, the insulating sheet 90 may be arranged at the inner bottom surface of the mold 200, and then the die pads 21a to 21d may be arranged at the insulating sheet 90 whose front surface is applied with adhesive.

After the arrangement step S103 is performed, a step of clamping the upper mold 201 and the lower mold 200 together is performed (mold clamping step S104). As a result, the lead frames 20, 30 are fixed with the molds 200, 201. In an embodiment of the present disclosure, for example, the main body portion 20a1 of the lead 20a is sandwiched and fixed between the molds 200 and 201 from above and below so as to be parallel to the horizontal plane. Note that in the mold clamping step S104, a part of each of the lead frames 20, 30 are exposed to the outside of the molds 200, 201.

Here, the part of the main body 20a1 close to the bent portion 20a2 warps upward, and the extending portion 20a3 causes the back surface of the die pad 21a to be pressed against the inner bottom surface of the mold 200. Accordingly, when the mold clamping step S104 is performed, the angle θ1 formed between the horizontal plane (here, for example, the front surface of the insulating sheet 90) and the back surface of the die pad 21a results in zero (see FIG. 4C). Further, in this event, the bent portion 20a2 is moved above the lead 20g (for example, the end portion 20g2) by the force received by the extending portion 20a3 from the inner bottom surface of the mold 200.

Accordingly, in the back surface of the die pad 21a, for example, a height h1 of the bent portion 20a2 from a predetermined point Px at which the extending portion 20a3 and the die pad 21a are connected is higher than a height h4 from the predetermined point Px to the front surface of the end portion 20g2. Note that the height from the predetermined point Px to the bent portion 20a2 is the height h1 in FIG. 4D, which will be described below, and the height from the predetermined point Px to the front surface of the end portion 20g2 is the height h4 in FIG. 4D, which will be described below.

Further, due to the aforementioned force, the height h1 of the bent portion 20a2 from the predetermined point Px is higher than the height h4 of the lead 20a at the point sandwiched between the molds 200 and 201 from the predetermined point Px. The height of the part of the lead 20a sandwiched between the molds 200 and 201 from the predetermined point Px is the height h4 in FIG. 4D, which will be described below. That is, in the mold clamping step S104, the back surface of the die pad 21a is pressed against the mold 200 such that the height h1 becomes higher than the height h4.

Although only the die pad 21a is illustrated in FIG. 4C, the angle θ1 formed between the horizontal plane (here, for example, the front surface of the insulating sheet 90) and each of the back surfaces of the die pads 21b to 21d results in zero as well. The respective bent portions 20b2 to 20d2 of the leads 20b to 20d are also moved above the lead 20g.

After the mold clamping step S104 is performed, the space inside the molds 200 and 201 is filled with a resin, for example, through a filling port (not illustrated) of the mold 201 (filling step S5). As a result, the respective bent portions 20a2 to 20d2 of the leads 20a to 20d are maintained in a state of being positioned above the lead 20g, for example. That is, each of the die pads 21a to 21d is maintained in a state of pressing the insulating sheet 90.

Thereafter, the molds 200, 201 are separated (mold separation step S6). As a result, the resin-sealed semiconductor device 10 is manufactured as illustrated in FIG. 4D. Note that the mold 200 corresponds to a “first mold,” and the mold 201 corresponds to a “second mold”.

The enlarged view of FIG. 4D illustrates the height h1 of the bent portion 20a2, the height h2 of the lead 20g, and the height h3 of the lead 30a with reference to the horizontal plane (the front surface of the insulating sheet 90 or the back surface of the die pad 21a). The leads 20g, 30a are not connected to any of the die pads 21a to 21d, and thus are not subjected to the force in the +Z direction. Whereas, as described above, the extending portion 20a3 of the lead 20a is connected to the die pad 21a that is inclined with respect to the horizontal plane. Thus, when the die pad 21a becomes horizontal (that is, the angle θ1 is zero), the lead 20a receives the force in the +Z direction from the die pad 21.

As a result, the height h1 of the bent portion 20a2 is higher than the height h2 of the lead 20g. Further, the height h1 of the bent portion 20a2 is higher than the height h3 of the lead 30a. In an embodiment of the present disclosure, the height h2 of the lead 20g is equal to the height h3 of the lead 30a. Here, the lead 20g has been described as an example of the lead that is not connected to any of the die pads, but it is not limited thereto. For example, the height h1 is higher than the respective heights of the leads 20e, 20f, 30b to 30f. That is, the height h1 is higher than the height of the lead that is not connected to any of the die pads. Although detailed description is omitted, the heights of the bent portions 20b2 to 20d2 also increase as with the height h1, and become higher than the height h2, for example.

Furthermore, as illustrated in FIG. 4D, the height h1 of the bent portion 20a2 is higher than the height h4 of the main body portion 20a1 of the lead 20a at the boundary position B1 between the inside and the outside of the resin 100. In an embodiment of the present disclosure, the heights of all the leads of the lead frame 20 and the lead frame 30 at the boundary positions between the inside and the outside of resin 100 are h4. Accordingly, the height of the main body 20g1 of the lead 20g at the boundary position B2 between the inside and the outside of the resin 100 and the height of the main body 30a1 of the lead 30a at the boundary position B3 between the inside and the outside of the resin 100 are the height h4.

It is assumed in an embodiment of the present disclosure that the front surface of the insulating sheet 90 or the back surface of the die pad 21a are used as a reference plane and is parallel to the horizontal plane, but it is not limited to thereto. For example, a reference surface (i.e., the back surface of the die pad 21a) may deviate by about 1° from the horizontal plane due to manufacturing variations and/or the like. For example, even in the case where the back surface of the die pad 21a deviates from the horizontal plane, the relationship among the heights h1 to h4 with reference to the back surface of the die pad 21a remains the same as the relationship thereamong when the horizontal plane is used as the reference.

As illustrated in FIG. 4D, the force from the die pad 21a to the insulating sheet 90 is strongest at a position close to the extending portion 20a3. In an embodiment of the present disclosure, the positions of the semiconductor chips 50a1 to 50a3 are adjusted in the front surface of the die pad 21a such that the die pad 21a can press the insulating sheet 90 even at a position away from the extending portion 20a3 in the +Y direction.

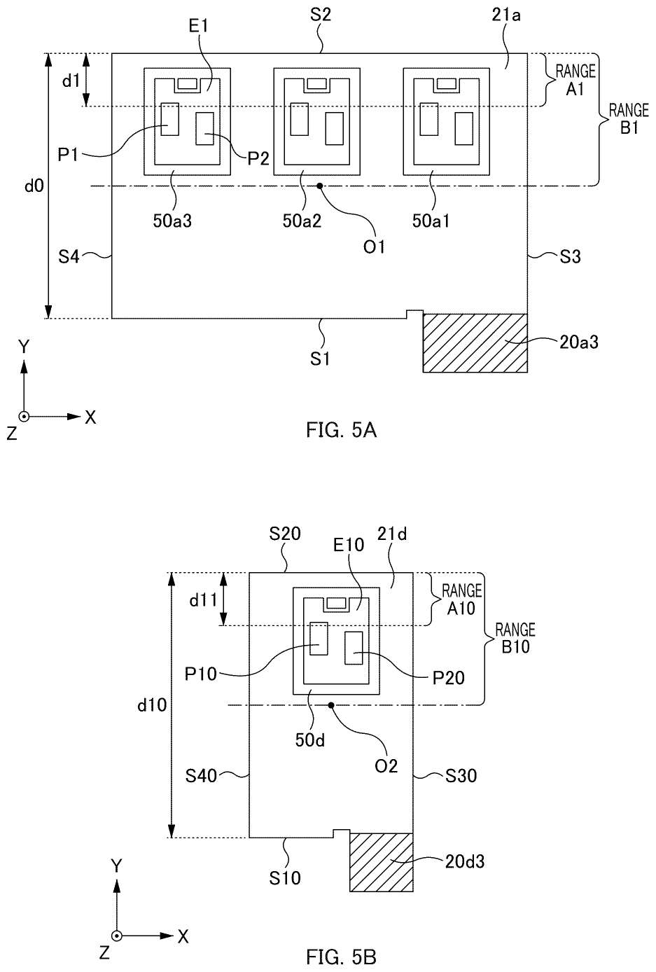

FIG. 5A is a diagram to describe the positions of the semiconductor chips 50a1 to 50a3 of the die pad 21a. Here, the four sides of the substantially quadrilateral die pad 21a in plan view (X-Y plane seen from the +Z direction) are defined as sides S1 to S4. The side S1 is a side on the −Y side of the die pad 21a, and the side S2 is a side facing the side S1. The sides S3 and S4 are a pair of sides that intersects each of the sides S1 and S2. The side S3 is a side on the +X side of the die pad 21a, and the side S4 is a side on the −X side facing the side S3.

FIG. 5A illustrates a center line (dashed-dotted line) that passes through the geometric center O1 of the die pad 21a and is parallel to the sides S1 and S2. Further, FIG. 5A illustrates a distance d1 (distance from the side S2), which is 20% of a distance d0, assuming that the distance d0 is a distance between the sides S1 and S2. Here, in the die pad 21a, the range corresponding to the distance d1 from the side S2 is defined as a range A1, and the range from the side S2 to the center line is defined as a range B1.

Note that the side S1 corresponds to a “first side”, the side S2 corresponds to a “second side”, the side S3 corresponds to a “third side”, and the side S4 corresponds to a “fourth side”. Further, the distance d1 corresponds to a “predetermined distance”, the range A1 corresponds to a “first range”, and the range B1 corresponds to a “second range”.

In an embodiment of the present disclosure, the extending portion 20a3 is connected to the end of the side S1 of the die pad 21a on the side S3 side (the end in the +X direction). Thus, in the die pad 21a, the force of the extending portion 20a3 pressing the die pad 21a downward decreases with increasing distance from the side S1 in the +Y direction. Further, in the die pad 21a, the force of the extending portion 20a3 pressing the die pad 21a downward decreases with increasing distance from the side S3 in the −X direction.

In an embodiment of the present disclosure, the semiconductor chips 50a1 to 50a3 are arranged such that at least the ends of the semiconductor chips 50a1 to 50a3 on the +Y side are included within the range A1 in the die pad 21a. Further, in the die pad 21a, the semiconductor chip 50a3 is arranged on the −X side (closer to the side S4) relative to the geometric center O1 of the die pad 21a.

Then, two wires W from the lead 20d are connected to the electrode E1 in the front surface of the semiconductor chip 50a3, at positions P1 and P2, respectively. That is, the positions P1 and P2 at which the two wires W are connected thereto are included within the range B1.

As a result, as illustrated in FIG. 4D, two wires W from the lead 20d results in pressing the semiconductor chip 50a3 and the die pad 21a downward at positions away from the extending portion 20a3. Although the description has been given here of the semiconductor chip 50a3 as an example among the semiconductor chips 50a1 to 50a3, the same applies to the connection positions of the electrodes of the semiconductor chips 50a1 and 50a2 and the wires.

FIG. 5B is a diagram to describe the position of the semiconductor chip 50d in the die pad 21d. Here, the four sides of the substantially quadrilateral die pad 21d in plan view (X-Y plane seen from the +Z direction) are defined as sides S10 to S40. The side S10 is a side on the −Y side of the die pad 21d, and the side S20 is a side on the +Y side facing the side S10. The sides S30, S40 are a pair of sides that intersects each of the sides S10 and S20. The side S30 is a side on the +X side of the die pad 21d, and the side S40 is a side on the −X side facing the side S30.

FIG. 5B illustrates a center line (dashed-dotted line) that passes through the geometric center O2 of the die pad 21d and is parallel to the sides S10 and S20. Further, FIG. 5B illustrates a distance d11 (distance from the side S20), which is 20% of a distance d10, assuming that the distance d10 is a distance between the sides S10 and S20. Here, in the die pad 21d, the range corresponding to the distance d11 from the side S20 is defined as a range A10, and the range from the side S20 to the center line is defined as a range B10.

In an embodiment of the present disclosure, the extending portion 20d3 is connected to the side S10 of the die pad 21d. Thus, in the die pad 21d, the force of the extending portion 20d3 pressing the die pad 21d downward decreases with increasing distance from the side S10 in the +Y direction.

In an embodiment of the present disclosure, the semiconductor chip 50d is arranged such that the end of the semiconductor chip 50d on the +Y side is included within the range A10 in the die pad 21d. Then, two wires W from the lead 20g are connected to the electrode E10 in the front surface of the semiconductor chip 50d, at positions P10 and P20, respectively. That is, the positions P10 and P20 at which these two wires are connected thereto are included within the range B10.

As a result, these two wires W from the lead 20g result in pressing the semiconductor chip 50d and the die pad 21d downward at positions away from the extending portion 20d3. Although the description has been given here of the semiconductor chip 50d as an example among the semiconductor chips 50b to 50d, the same applies to the semiconductor chips 50b, 50c (see FIG. 1).

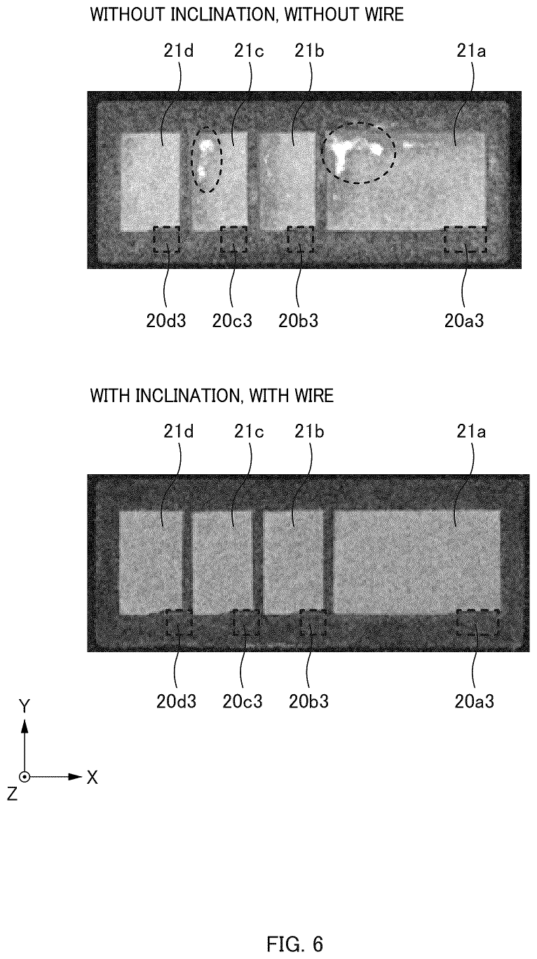

FIG. 6 is a diagram to describe the difference between the semiconductor device 10 and a comparative example. The upper part of FIG. 6 is an example of an image taken by an ultrasonic flaw detector, showing a state of adhesion between the insulating sheet 90 and the die pad 21a to 21d in a semiconductor device of the comparative example.

Here, in the semiconductor device of the comparative example, the die pads 21a to 21d are not inclined with respect to the horizontal plane. That is, the respective angles θ1 of the back surfaces of the die pads 21a to 21d are zero. Furthermore, in the semiconductor device of the comparative example, the wires are not connected to the semiconductor chips 50a1 to 50d, which are arranged at the die pads 21a to 21d. Note that the configuration is the same between the semiconductor device in the comparative example and the semiconductor device 10, except for the aforementioned two points.

In the semiconductor device of the comparative example, gaps are created between the insulating sheet 90 and the die pad 21a to 21d at places surrounded by dotted lines. In FIG. 6, where adhesion is good is indicated by a dark color, and where a gap is created is indicated by a light color.

On the other hand, as illustrated in the lower part of FIG. 6, the color is darker in the back surfaces of the die pads 21a to 21d of the semiconductor device 10 in an embodiment of the present disclosure. Accordingly, in the semiconductor device 10, it can be seen that the die pads 21a to 21d are tightly adhering to the insulating sheet 90 without a gap, as compared to the semiconductor device in the comparative example.

### SUMMARY

The above describes the semiconductor device 10 and the method of manufacturing the semiconductor device 10. In the semiconductor device 10, the height h1 of the bent portion 20a2 of the lead 20a is higher than the height h2 of the lead 20g, for example. The semiconductor device 10 as such does not need to use a pin to press the die pad 21a and the like, thereby being able to simplify the manufacturing process.

Further, in the die pad 21a, the end of the semiconductor chip 50a3 on the Y-side connected with the wire W is included in the range A1. This makes it possible to prevent a gap from forming between the die pad 21a and the insulating sheet 90 (for example, FIG. 4D).

Further, in the die pad 21a, for example, the semiconductor chip 50a3 is arranged closer to the side S4, out of the side S3 connected with the extending portion 20a3 and the side S4 (for example, FIG. 5A). This makes it possible to more reliably prevent a gap from forming between the die pad 21a and the insulating sheet 90.

Further, in the semiconductor chip 50a3, two wires W are connected to the positions P1 and P2 included in the range B1 (for example, FIG. 5A). This makes it possible to more reliably prevent a gap from forming between the die pad 21a and the insulating sheet 90.

Further, in the semiconductor device 10, the height h1 of the bent portion 20a2 of the lead 20a is higher than the height h4 of the main body portion 20a1 at the boundary position B1 between the inside and the outside of the resin 100 (for example, FIG. 4D). The semiconductor device 10 as such does not need to use a pin to press the die pad 21a and the like, thereby being able to simplify the manufacturing process. Note that the boundary position B1 corresponds to a “boundary portion” located at the boundary between the inside and the outside of the resin 100.

Further, the semiconductor device 10 can be manufactured by the method illustrated in FIG. 3, for example. For example, in the die pad 21a, the angle formed between the back surface of the die pad 21a and the horizontal plane at the lower end of the extending portion 20a3 is the angle θ1 (>0). The back surface of the die pad 21a is inclined downward (in the −Z direction) with respect to the horizontal plane, with increasing distance from the extending portion 20a3. Manufacturing the semiconductor device 10 having such a configuration by the method illustrated in FIG. 3, makes it possible to simplify the manufacturing process without using a pin to press the die pad 21a and the like.

Further, in the mold clamping step S104 of the manufacturing method in FIG. 3, the back surface of the die pad 21a is pressed against the mold 200. As a result, for example, the height h1 of the bent portion 20a2 from the predetermined point Px at which the extending portion 20a3 and the die pad 21a are connected is higher than the height h4 from the predetermined point Px to the front surface of the end portion 20g2 (for example, FIG. 4C). This makes it possible to simplify the manufacturing process without using a pin to press the die pad 21a and the like.

Further, in the mold clamping step S104 of the manufacturing method in FIG. 3, the back surface of the die pad 21a is pressed against the mold 200. As a result, for example, the height h1 of the bent portion 20a2 from the predetermined point Px is higher than the height h4 of the lead 20a from the predetermined point Px at the point thereof sandwiched between the molds 200 and 201 (see, for example, FIG. 4C). This makes it possible to simplify the manufacturing process without using a pin to press the die pad 21a and the like.

In an embodiment of the present disclosure, the distance d1 is set to 20% of the distance d0, but it is not limited thereto, as long as it is possible to prevent formation of a gap between the die pad 21 and the insulating sheet 90.

The present disclosure is directed to provision of a semiconductor device that can be manufactured with a simple process.

According to the present disclosure, it is possible to provide a semiconductor device that can be manufactured with a simple process.

An embodiment of the present disclosure described above is simply to facilitate understanding of the present disclosure and is not in any way to be construed as limiting the present disclosure. The present disclosure may variously be changed or altered without departing from its essential features and encompass equivalents thereof.

What is claimed is:

1. A semiconductor device, comprising:
a semiconductor chip;
a lead frame having
a die pad at which the semiconductor chip is arranged, and
a first lead and a second lead;
a wire that connects the lead frame and the semiconductor chip; and
a resin that seals the semiconductor chip,
the die pad having
a first surface at which the semiconductor chip is arranged, and
a second surface opposite to the first surface,
the first lead having
a first main body portion,
a bent portion located at an end of the first main body portion, and
an extending portion that extends from the bent portion to the die pad,
the second lead having
a second main body portion, and
an end portion that is located at an end of the second main body portion and inside the resin, and is separated from the die pad,
with reference to the second surface, a height of the bent portion being higher than a height of the second lead.

2. The semiconductor device according to claim 1, wherein
the die pad is of a substantially quadrilateral shape and has a first side and a second side facing each other in a plan view thereof,
the extending portion is connected to the die pad on a side of the first side,
the semiconductor chip is arranged at the die pad such that an end portion of the semiconductor chip on a side of the second side is in a first range, the first range corresponding to a predetermined distance from the second side of the die pad, and
the predetermined distance is 20% of a distance between the first side and the second side.

3. The semiconductor device according to claim 2, wherein
the die pad further has a third side and a fourth side facing each other and intersecting the first and second sides,
the extending portion is connected to the die pad on a side of the third side, and
the semiconductor chip is arranged at the die pad on a side of the fourth side.

4. The semiconductor device according to claim 2, wherein a position at which the wire is connected to the semiconductor chip is in a second range corresponding to a distance between a center line and the second side, the center line passing through a center of the die pad and being parallel to the second side, in the plan view.

5. A semiconductor device, comprising:
a semiconductor chip;
a lead frame having
a die pad at which the semiconductor chip is arranged, and
a first lead;
a wire that connects the lead frame and the semiconductor chip; and
a resin that seals the semiconductor chip,
the die pad having
a first surface at which the semiconductor chip is arranged, and
a second surface opposite to the first surface,
the first lead having
a first main body portion having a part extending from an inside of the resin to an outside thereof,
a bent portion located at an end of the first main body portion in the inside of the resin, and
an extending portion that extends from the bent portion to the die pad,
with reference to the second surface, a height of the bent portion being higher than a height of the first main body portion at a boundary portion between the inside and the outside of the resin.

6. A method of manufacturing a semiconductor device that includes
a semiconductor chip,
a die pad at which the semiconductor chip is arranged, and
a lead frame having a first lead, the first lead having
a first main body portion,
a bent portion located at an end of the first main body portion, and
an extending portion that extends from the bent portion to the die pad,
the die pad having
a first surface at which the semiconductor chip is arranged, and
a second surface opposite to the first surface, the second surface being inclined downward with respect to a horizontal plane with increasing distance from the extending portion, the method comprising:
a chip arrangement step of arranging the semiconductor chip at the first surface of the die pad;
a connection step of connecting the lead frame and the semiconductor chip with a wire;
an arrangement step of arranging, at a first mold, the lead frame and an insulating sheet located on a side of the second surface;
a mold clamping step of clamping the first mold and a second mold together; and
a filling step of filling a space between the first mold and the second mold with a resin.

7. The method of manufacturing the semiconductor device according to claim 6, wherein
the semiconductor device further includes
a second lead having
a second main body portion, and
an end portion located at an end of the second main body portion in an inside of the resin, and is separated from the die pad, and
the mold clamping step includes
exposing a part of each of the first main body portion of the first lead and the second main body portion of the second lead to an outside of the first mold and the second mold, and
causing the second surface to be pressed against the first mold such that a height of the bent portion of the first lead from a predetermined point of the second surface is higher than a height of the end portion of the second lead from the predetermined point in a space between the first mold and the second mold.

8. The method of manufacturing the semiconductor device according to claim 6, wherein
the mold clamping step includes
exposing a part of the first lead to an outside of the first mold and the second mold, and
causing the second surface to be pressed against the first mold such that a height of the bent portion of the first lead from a predetermined point of the second surface is higher than a height of a point thereof sandwiched between the first mold and the second mold from the predetermined point.
